(19) United States
(12) Patent Application Publication
(10) Pub. No.: US 2023/0359805 A1
(43) Pub. Date: Nov. 9, 2023

(54) LAYOUT METHOD FOR SEMICONDUCTOR CHIP, METHOD OF MANUFACTURING SEMICONDUCTOR CHIP USING THE SAME, AND COMPUTING DEVICE

(71) Applicant: SAMSUNG ELECTRONICS CO, LTD., Suwon-si (KR)

(72) Inventors: Kihyun KIM, Suwon-si (KR); Donyun KIM, Seoul (KR); Nohong KWAK, Suwon-si (KR)

(73) Assignees: SAMSUNG ELECTRONICS CO, LTD., Suwon-si (KR); SEOUL NATIONAL UNIVERSITY R&DB FOUNDATION, Seoul (KR)

(21) Appl. No.: 18/103,868

(22) Filed: Jan. 31, 2023

(30) Foreign Application Priority Data
May 3, 2022 (KR) 10-2022-0054825

(51) Int. Cl. G06F 30/398; G06T 7/00; G06T 7/70; G06F 30/392; G03F 1/70; G03F 1/36

(52) U.S. Cl. CPC G06F 30/398; G06T 7/0006; G06T 7/001; G06T 7/70; G06F 30/392; G03F 1/70; G03F 1/36; G06T 2207/10032; G06T 2207/10061; G06T 2207/20081; G06T 2207/30148; G06T 2207/20076

(57) ABSTRACT

A layout method for a semiconductor chip includes designing a layout; generating an aerial image based on the layout; determining a predicted scanning electron microscope (SEM) image based on the aerial image using a first machine learning model; determining a target SEM image based on the layout using a second machine learning model; predicting a defect in the semiconductor chip based on a result of comparing the predicted SEM image with the target SEM image; and correcting the layout based on the predicted defect.

### CROSS-REFERENCE TO RELATED APPLICATION(S)

This application is based on and claims priority under 35 U.S.C. § 119 to Korean Patent Application No. 10-2022-0054825 filed on May 3, 2022 in the Korean Intellectual Property Office, the disclosure of which is incorporated herein by reference in its entirety.

### BACKGROUND

Example embodiments of the disclosure relate to a layout method for a semiconductor chip, a method of manufacturing a semiconductor chip using the same, and a computing device.

Generally, patterns of a semiconductor chip may be formed in a photolithography process and an etching process. First, a layout for a pattern of a semiconductor chip formed on a wafer may be designed. When a mask is manufactured based on a layout, a circuit pattern on the mask may be transferred onto a wafer through an exposure process to form a circuit pattern (hereinafter, “transfer circuit pattern”) on the wafer. Process errors may be formed between the transfer circuit pattern on the wafer and the layout pattern. The process errors may be due to an optical proximity effect in an exposure process or a loading effect in an etching process.

Process errors may cause defects in a semiconductor chip. Even when a layout pattern is designed in compliance with design rules, defects may occur in the semiconductor chip due to process errors. The process errors of the semiconductor chip may be compensated for by correcting the layout pattern.

By predicting defects occurring in the semiconductor chip based on the layout and correcting the layout pattern in advance before the semiconductor chip is manufactured, a yield of the semiconductor process may improve.

### SUMMARY

An example embodiment of the disclosure provides a layout method for a semiconductor chip which may predict defects in a semiconductor chip and may correct a layout pattern based on a layout pattern, a method of manufacturing a semiconductor chip using the same, and a computing device.

An example embodiment of the disclosure provides a layout method for semiconductor chip which may eliminate defects in a semiconductor chip in advance by predicting defects in a semiconductor chip before forming a transfer circuit pattern on a wafer and correcting a layout pattern, a method of manufacturing a semiconductor chip using the same, and a computing device.

In accordance with an aspect of the disclosure, a layout method for a semiconductor chip includes designing a layout; generating an aerial image based on the layout; determining a predicted scanning electron microscope (SEM) image based on the aerial image using a first machine learning model; determining a target SEM image based on the layout using a second machine learning model; predicting a defect in the semiconductor chip based on a result of comparing the predicted SEM image with the target SEM image; and correcting the layout based on the predicted defect.

In accordance with an aspect of the disclosure, a method of manufacturing a semiconductor chip includes designing a layout; determining, using a first machine learning model, a predicted scanning electron microscope (SEM) image based on an aerial image generated based on the layout; predicting a defect in the semiconductor chip based on the predicted SEM image and generating a corrected layout based on the predicted defect; generating a final layout by performing optical proximity correction (OPC) on the corrected layout; manufacturing a mask using the final layout; and manufacturing the semiconductor chip using the mask.

In accordance with an aspect of the disclosure, a computing device for generating a layout of a semiconductor chip includes a memory configured to store at least one instruction; and a processor configured to execute the at least one instruction, wherein the processor designs the layout, generates an aerial image based on the layout, determines a predicted scanning electron microscope (SEM) image based on the aerial image using a first machine learning model, determines a target SEM image based on the layout using a second machine learning model, and corrects the layout according to a result of comparing the predicted SEM image with the target SEM image.

### BRIEF DESCRIPTION OF DRAWINGS

The above and other aspects, features, and advantages of the disclosure will be more clearly understood from the following detailed description, taken in combination with the accompanying drawings, in which:

FIG. 1 is a block diagram illustrating a computing system which may predict a defect in a semiconductor chip according to an example embodiment;

FIG. 2 is a flowchart illustrating a method of manufacturing a semiconductor chip according to an example embodiment;

FIG. 3 is a flowchart illustrating a layout method for a semiconductor chip according to an example embodiment;

FIG. 4 is a diagram illustrating a structure of a semiconductor substrate used for manufacturing a semiconductor chip and designing a layout of a semiconductor chip according to an example embodiment;

FIG. 5 is a diagram illustrating a method of generating machine learning models for predicting a defect in a semiconductor chip according to an example embodiment;

FIG. 6 is a diagram illustrating a method of generating machine learning models based on a generative adversarial network (GAN) according to an example embodiment;

FIGS. 7A to 8 are diagrams illustrating a method of predicting a defect in a semiconductor chip using machine learning models according to an example embodiment; and

FIG. 9 is a diagram illustrating an effect of predicting a defect in a semiconductor chip according to an example embodiment.

### DETAILED DESCRIPTION

Hereinafter, embodiments of the disclosure will be described as follows with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

At least one of the components, elements, modules or units (collectively “components” in this paragraph) represented by a block in the drawings may be embodied as various numbers of hardware, software and/or firmware structures that execute respective functions described above, according to an example embodiment. According to example embodiments, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Functional aspects of the above example embodiments may be implemented in algorithms that execute on one or more processors. Furthermore, the components represented by a block or processing steps may employ any number of related art techniques for electronics configuration, signal processing and/or control, data processing and the like.

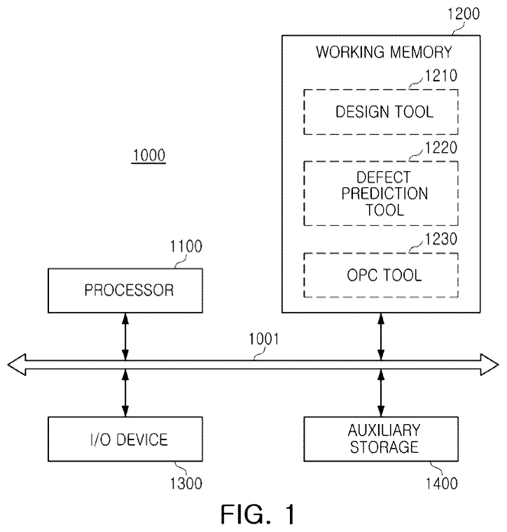

FIG. 1 is a block diagram illustrating a computing system 1000 which may design a layout of a semiconductor chip according to an example embodiment.

Referring to FIG. 1, a computing system 1000 may include at least one processor 1100 connected to a system bus 1001, a working memory 1200, an input/output device 1300, and an auxiliary storage device 1400.

The computing system 1000 may be configured as a dedicated device for generating/correcting a layout pattern or a dedicated device for designing a semiconductor including the same. For example, the computing system 1000 may include various design and verification simulation programs. The processor 1100, the working memory 1200, the input/output device 1300, and the auxiliary storage device 1400 may be electrically connected through the system bus 1001 and may exchange data with each other. An example embodiment of the system bus 1001 is not limited to the above-described example, and may further include mediation means for efficient management.

The processor 1100 may be implemented to execute at least one instruction. For example, the processor 1100 may be implemented to execute software (an application program, an operating system, and device drivers) to be executed in the computing system 1000. The processor 1100 may execute an operating system loaded into the working memory 1200. The processor 1100 may execute various application programs driven based on an operating system. For example, the processor 1100 may be implemented as a central processing unit (CPU), a microprocessor, an application processor (AP), or a processing device similar thereto.

The working memory 1200 may be implemented to store at least one instruction. For example, the working memory 1200 may be loaded with an operating system or application programs. When the computing system 1000 is booted, an OS image stored in the auxiliary storage device 1400 may be loaded into the working memory 1200 based on a boot sequence. Overall input/output operations of the computing system 1000 may be supported by the operating system. Similarly, application programs may be loaded into the working memory 1200 to be selected by a user or to provide a basic service. In particular, a design tool 1210 for designing a semiconductor layout, a defect prediction tool 1220 for predicting defects in a semiconductor chip based on a layout pattern and improving a layout pattern, or an OPC tool 1230 for correcting a layout pattern based on an optical proximity effect may be loaded into the working memory 1200 from the auxiliary storage device 1400.

Also, the working memory 1200 may be implemented as a volatile memory such as a dynamic random access memory (DRAM), a static random access memory (SRAM), or the like, or a nonvolatile memory such as a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), or the like.

The design tool 1210 may perform a function of changing the shapes and positions of specific layout patterns differently from those defined by a design rule (DR). Also, the design tool 1210 may perform a design rule check (DRC) on the changed bias data condition.

The defect prediction tool 1220 may predict a defect in a semiconductor chip which may be generated based on a layout including DRC-completed patterns. For example, the defect prediction tool 1220 may determine a defect position in which a transferred circuit pattern is expected to have a defect in the semiconductor chip region.

The defect prediction tool 1220 may predict a defect in a semiconductor chip using a machine learning model. For example, the defect prediction tool 1220 may learn defect information of a semiconductor chip based on a generative adversarial network (GAN) model. However, the type of network for learning defect information of a semiconductor chip is not limited to the aforementioned example.

The optical proximity correction (OPC) tool 1230 may perform OPC on the layout pattern. For example, the OPC may include an operation of correcting a rectangular layout pattern into one of a plurality of OPC shapes under a predetermined condition.

The input/output device 1300 may control a user input and output by user interface devices. For example, the input/output device 1300 may include input means such as a keyboard, a keypad, a mouse, and a touch screen and may receive information from a designer. The designer may, using the input/output device 1300, receive information on a semiconductor region or data paths requiring adjusted operating characteristics, and may receive images for detecting defects in a semiconductor chip. Also, the input/output device 1300 may include an output means such as a printer or a display and may display a process and result of processing of the design tool 1210, the defect prediction tool 1220, or the OPC tool 1230.

The secondary storage device 1400 may be provided as a storage medium of the computing system 1000. The auxiliary storage device 1400 may store application programs, an OS image, and various data. The secondary storage device 1400 may be provided in the form of a mass storage device such as a memory card (MMC, eMMC, SD, microSD, or the like), hard disk drive (HDD), solid state drive (SSD), universal flash storage (UFS), or the like.

The computing system 1000 may predict an SEM image of a semiconductor chip using a machine learning model, and may predict a defect position of the semiconductor chip based on the predicted SEM image.

A machine learning model may be generated using information representing various types of defects in a semiconductor chip. Ideally, a machine learning model may predict new types of defects not included in the information used to generate a machine learning model. However, when the amount of information used to generate a machine learning model is limited, it may be difficult for the machine learning model to effectively predict a defect in a semiconductor chip.

For example, when a machine learning model is generated using a layout pattern and an after clean inspection (ACI) contour image generated from the layout pattern, the amount of information used to generate the machine learning model may be limited. Specifically, the layout and ACI contour images may include only information about the presence or absence of a pattern in each position of the semiconductor chip region after the wafer is etched. In other words, the layout and ACI contour image may include only 1-bit information of 0 or 1 in each position of the semiconductor chip region. Accordingly, when a machine learning model generated using an ACI contour image is generated, the amount of information may be limited, such that it may be difficult for the machine learning model to effectively predict a new type of defect.

According to an example embodiment, a machine learning model may be generated using an aerial image and a scanning electron microscope (SEM) image corresponding to the aerial image. Also, an SEM image which may be generated based on a certain aerial image may be predicted using the machine learning model, and a defect in the semiconductor chip may be predicted using the predicted SEM image.

An aerial image may refer to an image of optical patterns irradiated on a wafer through a mask generated based on a layout. The aerial image may be represented as a grayscale image depending on intensity of light irradiated at each position on the wafer. For example, the aerial image may include 8-bit information of 0 to 255 at each position of the semiconductor chip region. Also, the aerial image may include information about a stochastic effect. For example, the aerial image may include information about the target patterns formed by light directly passing through the mask pattern, and also information about diffraction patterns formed around the target pattern by light diffracted through the mask pattern. That is, the amount of information of the aerial image may be greater than the amount of information of the layout or the ACI contour image.

According to an example embodiment, a machine learning model may be generated using an abundant amount of information, and an abundant amount of information may be used to predict whether a semiconductor chip includes a defect using the machine learning model. Thus, using the machine learning model, new types of defects not included in the information used to generate the machine learning model may also be predicted. Accordingly, since defects in the semiconductor chip may be effectively predicted from the layout and the layout may be corrected before the real semiconductor chip is manufactured, the time required for layout design may be reduced. Also, a yield of the semiconductor process may improve.

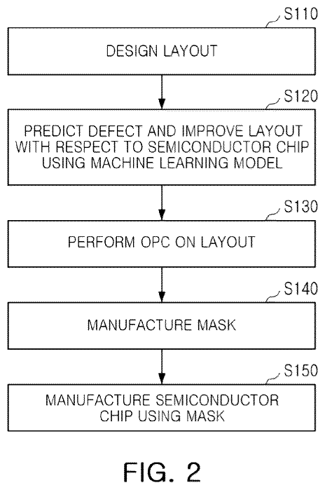

FIG. 2 is a flowchart illustrating a method of manufacturing a semiconductor chip according to an example embodiment.

Referring to FIG. 2, the method of manufacturing a semiconductor chip may include designing a design layout of a semiconductor chip (S110), predicting defects in the semiconductor chip using a machine learning model and improving the layout (S120), performing OPC on the improved layout (S130), manufacturing a mask using the layout corrected by OPC (S140), and manufacturing a semiconductor chip using the mask (S150).

In operation S110, a design layout corresponding to a circuit pattern of a semiconductor chip to be formed on a wafer may be provided from a host computer or server of a semiconductor manufacturing facility. Specifically, the layout may be a physical representation in which a circuit designed for a semiconductor chip may be transferred onto a wafer, and may include a plurality of patterns. For example, the design layout may be provided as coordinate values of contours of patterns included in the design layout from a computer aided design (CAD) system. In particular, the patterns may include repetitive patterns in which the same shape is repeated, and the patterns may be provided in a shape of a combination of polygons such as a triangle or a square.

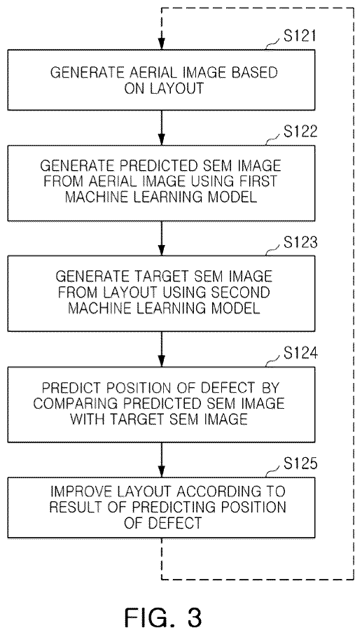

In operation S120, an aerial image may be generated based on the designed layout, and an SEM image corresponding to the aerial image may be predicted using a machine learning model. A defect in the semiconductor chip may be predicted based on the predicted SEM image, and the layout may be corrected based on the predicted defect. operation S120 will be described in greater detail with reference to FIG. 3.

In operation S130, the shape of the patterns included in the corrected layout may be changed to account for an error due to an optical proximity effect.

As the pattern is refined, an optical proximity phenomenon may occur due to influence between neighboring patterns during an exposure process. Accordingly, an optical proximity effect may be prevented by performing OPC for correcting the layout. For example, OPC may include extending an overall size of patterns included in the layout and processing corner portions. For example, OPC may include moving edges of each pattern or adding additional polygons. Using OPC, distortion of a pattern due to diffraction and interference of light generated during exposure may be corrected, and an error due to pattern density may be corrected. After the OPC operation, an OPC verification operation may be further performed.

The final layout data corrected by OPC may be transmitted to an exposure facility for manufacturing a mask to be used in an exposure process, such as a photomask and an electron beam mask. In operation S140, a mask may be manufactured by performing an exposure process on the mask substrate using the final layout data. After the exposure process, for example, a mask may be formed by further performing a series of processes such as development, etching, cleaning, and baking processes. In an example embodiment, a verification operation on the final layout data may be further performed before transmitting the final layout data.

Operation S150 may include performing an exposure process using a mask. The semiconductor chip may include a volatile memory such as a dynamic random access memory (DRAM), a static random access memory (SRAM), or the like, or a nonvolatile memory such as a flash memory, and may include a logic semiconductor device such as a micro-processor, such as, for example, a central processing unit (CPU), a controller, or an application specific integrated circuit (ASIC). In particular, the semiconductor chip may be manufactured by performing a process of forming second repetitive patterns on top of a lower structure including first repetitive patterns. The second repetitive patterns may be aligned with the first repetitive patterns by a mask with high accuracy. The semiconductor chip may be finally manufactured by further performing a deposition process, an etching process, an ion process, and a cleaning process in addition to the exposure process.

FIG. 3 is a flowchart illustrating a layout method for a semiconductor chip according to an example embodiment.

Referring to FIG. 3, the semiconductor chip layout method may include an operation of generating an aerial image based on a layout (S121), generating a predicted SEM image from the aerial image using a first machine learning model (S122), generating a target SEM image from the layout using a second machine learning model (S123), predicting a defect position by comparing the predicted SEM image with the target SEM image (S124), and improving the layout according to the result of predicting the defect position (S125). Operations S121 to S125 in FIG. 3 may be included in operation S120 in FIG. 2.

In operation S121, an aerial image may be generated based on the designed layout. An aerial image may be generated by simulation based on the layout. However, an example embodiment thereof is not limited thereto.

In operation S122, a predicted SEM image may be generated from the aerial image using a first machine learning model. The first machine learning model may be prepared in advance. A first machine learning model may be generated based on sample aerial images and sample SEM images corresponding to the sample aerial images. In other words, each of the sample SEM images may correspond to a respective sample aerial image.

The predicted SEM image may be an image of a transfer circuit pattern predicted to be formed on a wafer when a semiconductor chip is generated using the designed layout. The predicted SEM image may be used to predict a defect in a semiconductor chip. Meanwhile, a second machine learning model may be further used to predict a defect in a semiconductor chip from the predicted SEM image.

In operation S123, a target SEM image may be generated from the designed layout using the second machine learning model. The target SEM image may be an ideal SEM image which may be generated based on the designed layout. An ideal SEM image may refer to an SEM image corresponding to a semiconductor chip without any defect.

Meanwhile, the second machine learning model may be prepared in advance. The second machine learning model may be generated based on sample layouts and sample SEM images corresponding to the sample layouts. In other words, each of the sample SEM images may correspond to a respective sample layout.

In operation S124, the defect position of the semiconductor chip may be predicted by comparing the predicted SEM image with the target SEM image. For example, to compare the predicted SEM image with the target SEM image, the predicted SEM image and the target SEM image may overlap each other, and a position in the predicted SEM image which does not overlap the target SEM image may be predicted as a defect position. However, the method of comparing the predicted SEM image with the target SEM image is not limited to the aforementioned example.

In operation S125, the layout may improve according to the result of predicting the defect position. For example, the layout may improve by correcting the size, position, shape, or the like, of the layout pattern in or around the defect position in the layout.

In example embodiments, operations S121 to S125 may be repeatedly performed for the improved layout. In other words, the output of operation S125 (e.g., the improved layout) may be used as an input layout of operation S121. Operations S121 to S125 may be repeatedly performed until overall defects in the layout are corrected.

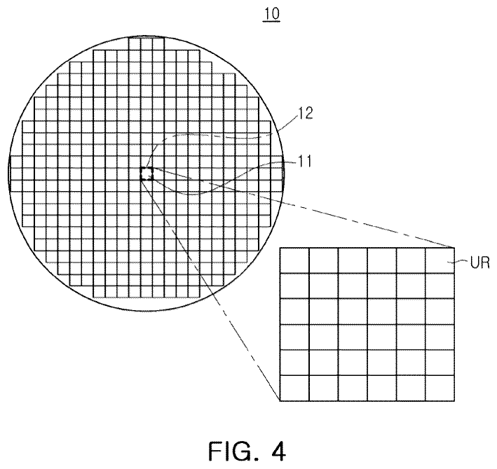

FIG. 4 is a diagram illustrating a structure of a semiconductor substrate used for manufacturing a semiconductor chip and designing a layout of a semiconductor chip according to an example embodiment.

Referring to FIG. 4, a predetermined pattern may be formed on the semiconductor substrate 10 such that a plurality of semiconductor chips 11, which are independently drivable units, may be formed. The semiconductor substrate 10 may include, for example, silicon (Si), such as crystalline Si, polycrystalline Si, or amorphous Si. Alternatively, the semiconductor substrate 10 may include at least one compound semiconductor selected from among a semiconductor element such as germanium (Ge), silicon germanium (SiGe), silicon carbide (SiC), gallium arsenide (GaAs), indium arsenide (InAs), and indium phosphide (InP). Alternatively, the semiconductor substrate 10 may have a silicon on insulator (SOI) structure. For example, the semiconductor substrate 10 may include a buried oxide layer (BOX). The semiconductor substrate 10 may include a conductive region, that is, for example, a well doped with an impurity or a structure doped with impurities.

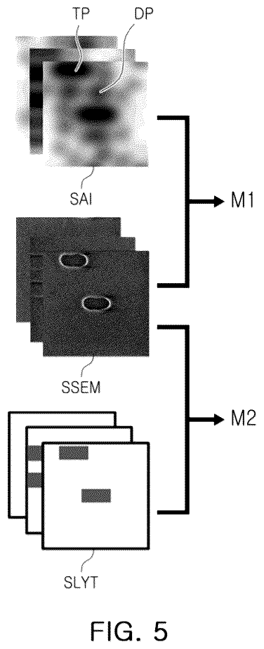

The exposure process may be performed by configuring one or more semiconductor chips 11 as a field 12, which is a repeating unit, in a mask (reticle) for forming a pattern and dividing the entire semiconductor substrate 10 into several regions. The exposure process may be performed by, for example, deep ultraviolet (DUV) light, extreme ultraviolet (EUV) light, or electron beam (E-beam). The exposure process may be performed by, for example, a scanner, a stepper or a step-and-scan tool. In the example in FIG. 5, a single field 12 may include a single semiconductor chip 11, and in the photo process of each operation, a single semiconductor chip 11 may be formed on the semiconductor substrate 10 due to a one shot using a mask in which the field 12 is formed. However, an example embodiment thereof is not limited thereto, and a single field 12 may include 2 to 8 memory chips 11.

Referring to FIG. 4, one field 12 may be divided into a plurality of unit regions UR. For example, the horizontal and vertical lengths of the field 12 may be several mm to several cm, and the horizontal and vertical lengths of the unit region UR may be several μm. In example embodiments, the first and second machine learning models may be generated using sample aerial images, sample layouts, and sample SEM images of the plurality of unit regions UR. Also, the operation of generating the predicted SEM image, the operation of generating the target SEM image, and the operation of comparing the predicted SEM image and the target SEM image may be performed for each unit region UR.

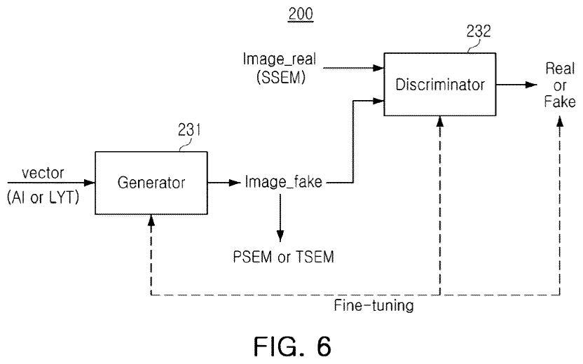

Hereinafter, a method of generating the first and second machine learning models will be described in greater detail with reference to FIGS. 5 to 6.

FIG. 5 is a diagram illustrating a method of generating machine learning models for predicting a defect in a semiconductor chip according to an example embodiment.

FIG. 5 illustrates sample aerial images SAI, sample SEM images SSEM, and sample layouts SLYT. The sample aerial images SAI, the sample SEM images SSEM, and the sample layouts SLYT may be prepared in advance to generate machine learning models.

Referring to FIG. 5, a first machine learning model M1 may be generated using the sample aerial images SAI and the sample SEM images SSEM. The sample aerial images SAI and the sample SEM images SSEM may correspond to the same unit region UR of the field 12 of the wafer.

The first machine learning model M1 may be trained to predict SEM images of a transfer circuit pattern formed on the wafer when an optical pattern such as an aerial image is irradiated on the wafer using the sample aerial images SAI and the sample SEM images SSEM as an input.

Meanwhile, the sample aerial image SAI for generating the first machine learning model M1 may be obtained in various manners. As a first example, the sample aerial image SAI may be obtained through layout-based simulation. As a second example, the sample aerial image SAI may be obtained using an aerial image measurement system (AIMS), which is equipment for measuring an optical pattern irradiated on a wafer through a mask generated based on a layout.

In the example in FIG. 5, the sample aerial image SAI may be obtained based on a sample layout SLYT. When the sample aerial image SAI is compared with the sample layout SLYT, the sample aerial image SAI may include the target patterns TP formed in the same position as the layout patterns and the diffraction patterns formed around the layout patterns DP. That is, the amount of information included in each of the sample aerial images SAI may be greater than the amount of information of the corresponding sample layout LYT.

The sample SEM image SSEM may be obtained by imaging the surface of the wafer on which the transfer circuit pattern is formed using SEM.

The second machine learning model M2 may be generated using the sample layouts SLYT and the sample SEM images SSEM. The sample layouts SLYT and the sample SEM images SSEM may correspond to the same unit region UR of the field 12 of the wafer.

The second machine learning model M2 may be trained to predict a target SEM image to be formed on a wafer based on the layout by receiving the sample layouts SLYT and the sample SEM images SSEM as inputs.

As described with reference to operation S123 in FIG. 3, the target SEM image generated using the second machine learning model M2 may correspond to an ideal SEM image which may be generated based on the layout. For example, the transfer circuit patterns appearing in the ideal SEM image may be disposed in the same position as the layout patterns, and the size of the transfer circuit patterns may have a difference from the size of the layout patterns within a predetermined range.

FIG. 5 illustrates the example in which the same sample SEM images SSEM are used as inputs to both of the first machine learning model M1 and the second machine learning model M2. However, an example embodiment thereof is not limited thereto, and first sample SEM images may be used when generating the first machine learning model M1, and second sample SEM images different from the first sample SEM images may be used when the second machine learning model M2 is generated. The first sample SEM images and the second sample SEM images may be images obtained by imaging different unit regions UR in the field 12 included in the wafer. Also, the first sample SEM images may include both SEM images having defects and SEM images having no defect, but SEM images having no defect may be selected as the second sample SEM images. By generating the second machine learning model M2 using the SEM images having no defect, the second machine learning model M2 may output an ideal SEM image when the layout is input.

FIG. 6 is a diagram illustrating a method of generating machine learning models based on a generative adversarial network (GAN) according to an example embodiment.

The machine learning model 200 may acquire defect information which may be generated on a wafer through machine learning based on GAN. The machine learning model 200 may be included in the defect prediction tool 1220 in FIG. 1, and may be driven by the processor 1100 in FIG. 1.

Referring to FIG. 6, the machine learning model 200 based on GAN may include a generator 231 and a discriminator 232.

The generator 231 may receive an input vector (e.g., from a first external entity) and may generate a fake image Image_fake based on an input vector. When the machine learning model 200 is the first machine learning model M1, the input vector may be a sample aerial image. Also, when the machine learning model 200 is the second machine learning model M2, the input vector may be a sample layout. The fake image Image_fake may correspond to an SEM image output by the machine learning model 200 based on an input vector.

The discriminator 232 may receive a real image Image_real or a fake image Image_fake and may determine whether the input image is a real image or a fake image. The real image Image_real may be a sample SEM image input to the machine learning model 200 (e.g., from a second external entity which may be the same as or different from the first external entity).

The machine learning model 200 is trained so that the discriminator 232 can more accurately discriminate between the real image Image_real and the fake image Image_fake, and the generator 231 can generate fake image Image_fake which is difficult to distinguish whether the fake image Image_fake is true or false by the discriminator 232.

Machine learning for the discriminator 232 may be performed to determine the real image Image_real as being true and may determine the fake image Image_fake as being false. The discriminator 232 may perform various operations such as a convolution operation, a pooling operation, a down sampling operation, a multiplication operation, an addition operation, and an activation operation with respect to the input real image Image_real or the input fake image Image_fake. The discriminator 232 may output a signal indicating whether the input image is true or false through various operations. When the discriminator 232 determines the real image Image_real as false or determines the fake image Image_fake as true, the machine learning model 200 may adjust the weights or biases of nodes included in the discriminator 232. The machine learning for the discriminator 232 may be completed when a probability that the real image Image_real is determined to be true by the discriminator 232 and a probability that the fake image Image_fake is determined to be false converge to 50%.

Machine learning on the generator 231 may be performed such that the fake image Image_fake generated from the generator 231 is determined to be true by the discriminator 232. The generator network 231 may perform various operations such as a deconvolution operation, an unpooling operation, an up-sampling operation, a multiplication operation, an addition operation, and an activation operation on an input vector. The generator 231 may generate a fake image Image_fake based on the input vector through various operations. When the discriminator 232 determines that the fake image Image_fake is false, the machine learning model 200 may update or adjust weights or biases of nodes included in the generator 231. The machine learning for the generator 231 may be completed when a probability that the fake image Image_fake generated by the generator 231 is determined to be true by the discriminator is converged to 50%.

When the machine learning for the discriminator 232 and the generator 231 is completed, the generator 231 may generate a fake image Image_fake close to the real image Image_real to the extent that it may be difficult to distinguish the fake image Image_fake from the real image Image_real. For example, when an aerial image is input to the generator 231 of the first machine learning model M1 on which the secondary machine learning has been completed, the generator 231 may generate a fake image Image_fake close to the real image Image_real, and the generated fake image Image_fake may be output as a predicted SEM image PSEM. Similarly, when a layout is input to the generator 231 of the second machine learning model M2 on which the secondary machine learning has been completed, the target SEM image TSEM may be output by the generator 231.

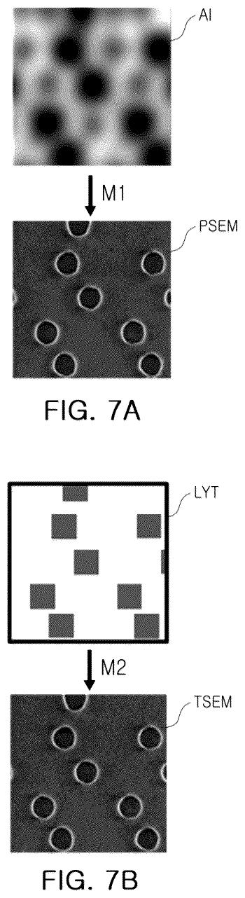

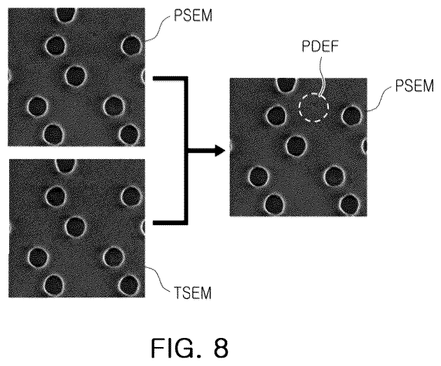

FIGS. 7A to 8 are diagrams illustrating a method of predicting a defect in a semiconductor chip using machine learning models according to an example embodiment.

FIG. 7A illustrates an aerial image AI and a predicted SEM image PSEM. Referring to FIG. 7A, the predicted SEM image PSEM may be determined based on the aerial image AI using the first machine learning model M1. FIG. 7A corresponds to operation S122 in FIG. 3.

By using the first machine learning model M1, even when an aerial image AI having a pattern different from that of the sample aerial image SAI described with reference to FIG. 5 is input, a predicted SEM image PSEM may be generated. For example, when the aerial image AI is input to the generator 231 described with reference to FIG. 6, the predicted SEM image PSEM may be output by the generator 231. The predicted SEM image PSEM output by the generator 231 may be close to a transfer circuit pattern which may be actually formed on the wafer when the aerial image AI is irradiated to the wafer.

The aerial image AI may be generated based on a layout designed for manufacturing a semiconductor chip. The aerial image AI may be generated through a simulation based on a layout. However, an example embodiment thereof is not limited thereto, and the aerial image AI may be generated by actually measuring an optical pattern irradiated by passing through a mask generated based on the layout. When generating the aerial image AI based on the layout, by using the first machine learning model M1, a transfer circuit pattern which may be actually formed on the wafer may be predicted based on the layout.

FIG. 7B illustrates a layout LYT and a target SEM image TSEM. Referring to FIG. 7B, the target SEM image TSEM may be determined based on the layout LYT using the second machine learning model M2. FIG. 7B corresponds to operation S123 in FIG. 3.

By using the second machine learning model M2, even when a layout LYT having a pattern different from the sample layout SLYT described with reference to FIG. 5 is input, the target SEM image TSEM may be generated. SEM images having no defect SSEM may be used to generate the second machine learning model M2 as described with reference to FIG. 3. The target SEM image TSEM generated using the second machine learning model M2 may correspond to an ideal transfer circuit pattern targeted to be formed on the wafer based on the layout LYT.

FIG. 8 is a diagram illustrating a method of predicting a defect position by comparing the predicted SEM image PSEM with the target SEM image TSEM. FIG. 8 corresponds to operation S124 in FIG. 3.

As described with reference to FIG. 7B, the target SEM image TSEM may represent a transfer circuit pattern having no defect. Accordingly, the defect position may be predicted from the predicted SEM image PSEM by comparing the predicted SEM image PSEM with the target SEM image TSEM image.

According to an example embodiment, a die-to-die technique for determining a defect by comparing the predicted SEM image PSEM with the target SEM image TSEM may be used. For example, the die-to-die technique may include overlapping the predicted SEM image PSEM and the target SEM image TSEM, and determining the position in the predicted SEM image PSEM which does not overlap the target SEM image TSEM as a defect position. As described with reference to FIG. 4, a single field 12 may include a plurality of unit regions UR. As determination of a defect through the die-to-die technique is performed for each of the plurality of unit regions UR, a defect in the layout of the field 12 may be determined.

In example embodiments, the defect position may be determined by comparing the layout patterns with the transfer circuit patterns appearing on the SEM image. However, when it is determined whether the sizes and positions of the corresponding transfer circuit patterns match the layout patterns for overall layout patterns, the amount of computation may increase. Alternately, when the die-to-die technique is used, it may not be necessary to perform calculations on overall transfer circuit patterns, and defects may be determined by only finding non-overlapping positions in the overlapping SEM image. Accordingly, when the die-to-die technique is used based on the predicted SEM image and the target SEM image, the amount of computation for defect prediction may be reduced and the defect prediction may be performed swiftly.

In the example in FIG. 8, a position in which the predicted SEM image PSEM and the target SEM image TSEM do not overlap each other may be indicated. No pattern may appear in the corresponding position of the target SEM image TSEM, whereas a fine dot pattern may be present in the corresponding position of the predicted SEM image PSEM. In this case, the position in which the dot pattern of the predicted SEM image PSEM is present may be determined as the predicted defect position PDEF.

Once the predicted defect position PDEF is determined, the surrounding pattern of the predicted defect position PDEF in the layout may be corrected. For example, the shape, position, and size, of the layout patterns around the predicted defect position PDEF may be corrected.

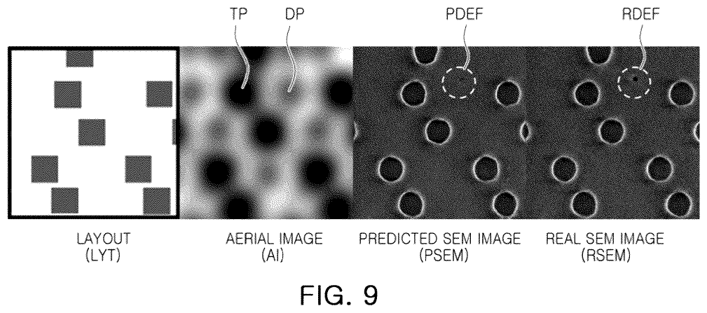

FIG. 9 is a diagram illustrating an effect of predicting a defect in a semiconductor chip according to an example embodiment.

FIG. 9 illustrates a layout LYT, an aerial image AI, a predicted SEM image PSEM, and a real SEM image RSEM. The layout LYT, the aerial image AI, and the predicted SEM image PSEM may be the same as the images illustrated in FIGS. 7A and 7B.

The aerial image AI may be an image generated based on the layout LYT. The aerial image AI may include target patterns TP formed in the same position as the layout patterns and diffraction patterns DP formed around the layout patterns.

The predicted SEM image PSEM may be an image generated based on the first machine learning model M1 according to an example embodiment based on the aerial image AI. As described with reference to FIG. 8, a predicted defect position PDEF may be determined from the predicted SEM image PSEM.

The real SEM image RSEM may represent an SEM image of a transfer circuit pattern actually formed on the wafer as a result of irradiating light on the wafer using a mask generated based on the layout. Referring to the real SEM image RSEM of FIG. 9, a dot-shaped pattern may be generated in a position in which there should be no transfer circuit pattern. The dot-shaped pattern may be formed by diffracted light when irradiating light to the wafer through a mask pattern. A position in which the dotted pattern is generated may be indicated as a real defect position (RDEF).

The predicted SEM image PSEM may be generated based on the aerial image AI including the diffraction pattern DP. The effect of diffracted light may be reflected in the transfer circuit pattern predicted from the predicted SEM image PSEM. Referring to FIG. 9, the predicted defect position PDEF predicted using the predicted SEM image PSEM may have the same position as the real defect position RDEF.

According to an example embodiment, by generating a predicted SEM image PSEM based on an aerial image AI using a first machine learning model M1, and predicting a defect position based on the predicted SEM image PSEM, a position in which a defect may occur in a real semiconductor chip may be detected. By correcting the layout pattern around the defect position in advance before manufacturing the semiconductor chip, a yield of the semiconductor process may effectively improve.

According to an example embodiment, by generating a target SEM image TSEM based on the layout LYT using the second machine learning model M2 and comparing the target SEM image TSEM with the predicted SEM image PSEM, defects in the semiconductor chip may be predicted. By predicting the defect through comparison between SEM images, the amount of computation required for predicting the defect may be reduced.

According to the aforementioned example embodiments, the layout method for a semiconductor chip, the method of manufacturing a semiconductor chip using the same, and the computing device may predict a defect in a semiconductor chip using a machine learning model which may determine a predicted SEM image based on an aerial image having grayscale information.

Also, the layout method for a semiconductor chip, the method of manufacturing a semiconductor chip using the same, and the computing device may predict new types of defects which may not be expected at the time of creating a machine learning model.

Also, the layout method for a semiconductor chip, the method of manufacturing a semiconductor chip using the same, and the computing device may predict a defect in the semiconductor chip by comparing the predicted SEM image determined based on the aerial image with the target SEM image determined based on the layout. By comparing the SEM images, a defect in the semiconductor chip may be swiftly predicted.

While example embodiments have been illustrated and described above, it will be apparent to those skilled in the art that modifications and variations could be made without departing from the scope of the disclosure as defined by the appended claims.

What is claimed is:

1. A layout method for a semiconductor chip, the method comprising:
designing a layout;
generating an aerial image based on the layout;
determining a predicted scanning electron microscope (SEM) image based on the aerial image using a first machine learning model;
determining a target SEM image based on the layout using a second machine learning model;
predicting a defect in the semiconductor chip based on a result of comparing the predicted SEM image with the target SEM image; and
correcting the layout based on the predicted defect.

2. The layout method of claim 1, further comprising:
generating the first machine learning model by performing machine learning using a plurality of sample aerial images and a plurality of first sample SEM images,
wherein each of the plurality of first sample SEM images corresponds to a respective sample aerial image from among the plurality of sample aerial images.

3. The layout method of claim 2, further comprising:
generating the second machine learning model by performing machine learning using a plurality of sample layouts and a plurality of second sample SEM images,
wherein each of the plurality of second sample SEM images corresponds to a respective sample layout from among the plurality of sample layouts.

4. The layout method of claim 3, wherein the plurality of first sample SEM images are the same as the plurality of second sample SEM images.

5. The layout method of claim 3, wherein the plurality of first sample SEM images are of a region different from a region of the plurality of second sample SEM images are of different regions of the semiconductor chip.

6. The layout method of claim 3, wherein the plurality of second sample SEM images comprise SEM images having no defects.

7. The layout method of claim 3,
wherein a region of the semiconductor chip comprises a plurality of unit regions, and
wherein each of the plurality of sample aerial images, each of the plurality of sample layouts, each of the plurality of first sample SEM images, and each of the plurality of second sample SEM images corresponds to a respective unit region from among the plurality of unit regions.

8. The layout method of claim 3, further comprising:
obtaining each of the plurality of sample aerial images by measuring an optical pattern irradiated to a wafer through a mask generated based on a respective sample layout from among the plurality of sample layouts.

9. The layout method of claim 3, further comprising:
obtaining each of the plurality of sample aerial images by performing a simulation based on a respective sample layout from among the plurality of sample layouts.

10. The layout method of claim 1, wherein the first machine learning model and the second machine learning model comprise a generative adversarial network (GAN) model.

11. The layout method of claim 1, wherein the predicting the defect in the semiconductor chip comprises:
allowing the predicted SEM image and the target SEM image to overlap each other; and
predicting a position of the predicted SEM image which does not overlap the target SEM image as a defect position.

12. The layout method of claim 1, wherein the aerial image comprises grayscale information in each position of the aerial image.

13. The layout method of claim 1, wherein the aerial image comprises:
target patterns formed in the same position as patterns of the layout; and
diffraction patterns formed around the target patterns.

14. The layout method of claim 1, wherein the correcting the layout based on the predicted defect comprises adjusting a position, a size or a shape of a pattern of the layout around a position in which the defect is predicted.

15. The layout method of claim 1, further comprising:
using the corrected layout, repeating the generating the aerial image, the determining the predicted SEM image, the determining the target SEM image, and the predicting the defect in the predicted SEM image.

16. A method of manufacturing a semiconductor chip, the method comprising:
designing a layout;
determining, using a first machine learning model, a predicted scanning electron microscope (SEM) image based on an aerial image generated based on the layout;
predicting a defect in the semiconductor chip based on the predicted SEM image and generating a corrected layout based on the predicted defect;
generating a final layout by performing optical proximity correction (OPC) on the corrected layout;
manufacturing a mask using the final layout; and
manufacturing the semiconductor chip using the mask.

17. The method of claim 16, wherein the predicting the defect in the semiconductor chip based on the predicted SEM image comprises:
determining a target SEM image based on the layout using a second machine learning model; and
predicting a defect in the predicted SEM image based on a result of comparing the predicted SEM image with the target SEM image.

18. A computing device for generating a layout of a semiconductor chip, the computing device comprising:
a memory configured to store at least one instruction; and
a processor configured to execute the at least one instruction,
wherein the processor designs the layout, generates an aerial image based on the layout, determines a predicted scanning electron microscope (SEM) image based on the aerial image using a first machine learning model, determines a target SEM image based on the layout using a second machine learning model, and corrects the layout according to a result of comparing the predicted SEM image with the target SEM image.

19. The computing device of claim 18,
wherein the first machine learning model comprises:
a generator configured to receive a sample aerial image from a first external entity and to output a fake SEM image; and
a discriminator configured to receive a first sample SEM image from a second external entity or to receive the fake SEM image from the generator, and to determine whether the received SEM image is a real image or a fake image, and
wherein the first machine learning model is trained such that the probability that the fake SEM image generated by the generator is determined as a real image by the discriminator converges to 50%, and outputs the fake SEM image as the predicted SEM image.

20. The computing device of claim 18,
wherein the second machine learning model comprises:
a generator configured to receive a sample layout from a first external entity and to output a fake SEM image; and
a discriminator configured to receive a second sample SEM image from a second external entity or to receive the fake SEM image from the generator, and to determine whether the received SEM image is a real image or a fake image, and
wherein the second machine learning model is trained such that the probability that the fake SEM image generated by the generator is determined as a real image by the discriminator converges to 50%, and outputs the fake SEM image close to the real image as the target SEM image.
